(19) United States
(12) Patent Application Publication
(10) Pub. No.: US 2012/0085987 A1
(43) Pub. Date: Apr. 12, 2012

(54) LIGHT EMITTING DEVICE

(75) Inventors: Rong Xuan, Taipei County (TW); Po-Chun Liu, Taichung County (TW); Ren-Hao Jiang, Taichung City (TW)

(73) Assignee: INDUSTRIAL TECHNOLOGY RESEARCH INSTITUTE, Hsinchu (TW)

(21) Appl. No.: 12/902,162

(22) Filed: Oct. 12, 2010

(51) Int. Cl. H01L 33/04

(52) U.S. Cl. 257/13; 257/E33.016

(57) ABSTRACT

A light emitting device is provided, which includes a light-emitting structure having an active layer and a magnetic material. The active layer includes at least one quantum well structure, and a thickness of at least one of the quantum well structure is greater than or substantially equal to 1.2 nm at room temperature. The magnetic material is coupled with the light-emitting structure to produce a magnetic field perpendicular to a surface of the active layer in the light-emitting structure.

### 1. TECHNICAL FIELD

The disclosure generally relates to a light emitting device, and in particular, to a light emitting device with a magnetic field.

### 2. BACKGROUND

Light emitting devices, such as a light emitting diode (LED) can emit light due to recombination of electrons and holes in the active layer thereby generating light, wherein the electrons and the holes are provided from N- and P-type regions respectively. Due to advantages of long lifespan, small volume, low driving voltage/current, high shock absorption, low heat, power saving and good luminous efficiency as compared with conventional lamps, LED has been widely used in household appliances and light sources of various instruments. In recent years, LED is developing towards high output efficiency and high luminance, so that the applications of LED can be expanded to mega-size display board, traffic light, and so on.

However, if carrier density is not uniformly distributed to a whole light emitting area, light uniformity is impacted. Moreover, light output efficiency of the LED is usually determined by various factors, and internal quantum efficiency (IQE) among said factors refers to the recombination ratio of electrons and holes occurring in the active layer. It has been observed that the LED of conventional design usually suffers from low IQE, resulting in reduction of the output light, so that the application of the LED is quite restricted. Accordingly, how to improve the light uniformity and output efficiency of the LED still need further development in the field of the art.

### SUMMARY

According to an embodiment, a light emitting device is provided, which includes a light-emitting structure having an active layer and a magnetic material. The active layer includes at least one quantum well structure, and a thickness of at least one of the quantum well structure is greater than or substantially equal to 1.2 nm at room temperature. The magnetic material is coupled with the light-emitting structure to produce a magnetic field that at least has a component perpendicular to a surface of the active layer in the light-emitting structure.

As mentioned above, according another embodiment, the magnetic material is integrated into the structure of the light emitting device. In other words, the magnetic field is separately self-supplied in a single light emitting device. The single light emitting device can also be easily packaged into a chip. Therefore, the magnetic field can be applied to the light emitting device in the manners as described above, so as to enhance the light emitting efficiency and increase the luminance of the light emitting device.

In order to make the aforementioned and other features and advantages of the disclosure more comprehensible, several embodiments accompanied with figures are described in detail below.

### BRIEF DESCRIPTION OF THE DRAWINGS

The accompanying drawings are included to provide a further understanding of the disclosure, and are incorporated in and constitute a part of this specification. The drawings illustrate embodiments of the disclosure and, together with the description, serve to explain the principles of the disclosure.

FIG. 1 depicts, in a cross-sectional view, a light emitting device according to an embodiment of the disclosure.

FIG. 2 schematically illustrates a band structure (a) without and (b) with the application of the magnetic field.

FIG. 3 is a schematic cross-sectional diagram illustrating a light emitting device according to an embodiment of the disclosure.

FIGS. 4A-4C schematically illustrate distribution curves of pumping power of laser versus PL intensity of a light emitting device under various conditions of applying the magnetic field according to three experimental examples, respectively.

FIG. 5A schematically illustrates distribution curves of injection current versus output power of a light emitting device under various conditions of applying the magnetic field according to an experimental example.

FIG. 5B schematically illustrates distribution curves of pumping power of laser versus PL intensity of a light emitting device under various conditions of applying the magnetic field according to an experimental example.

FIGS. 5C and 5D schematically illustrate distribution curves of injection current and pumping power of laser versus wavelength of light emitted by the light emitting device in accordance with the experimental examples depicted in FIGS. 5A and 5B, respectively.

### DESCRIPTION OF THE EMBODIMENTS

Reference will now be made in detail to the present embodiments of the disclosure, examples of which are illustrated in the accompanying drawings. Wherever possible, the same reference numbers are used in the drawings and the description to refer to the same or like parts.

In physical phenomenon, the Hall effect is well known that when a current flow through a conductive line and an external magnetic field is applied transversely, then the path of the current, such as the electron current, is also transversely shifted due to magnetic Lorenz force of F=q(v×B). The disclosure involves the consideration of the Hall effect and implements the Hall effect into light emitting devices.

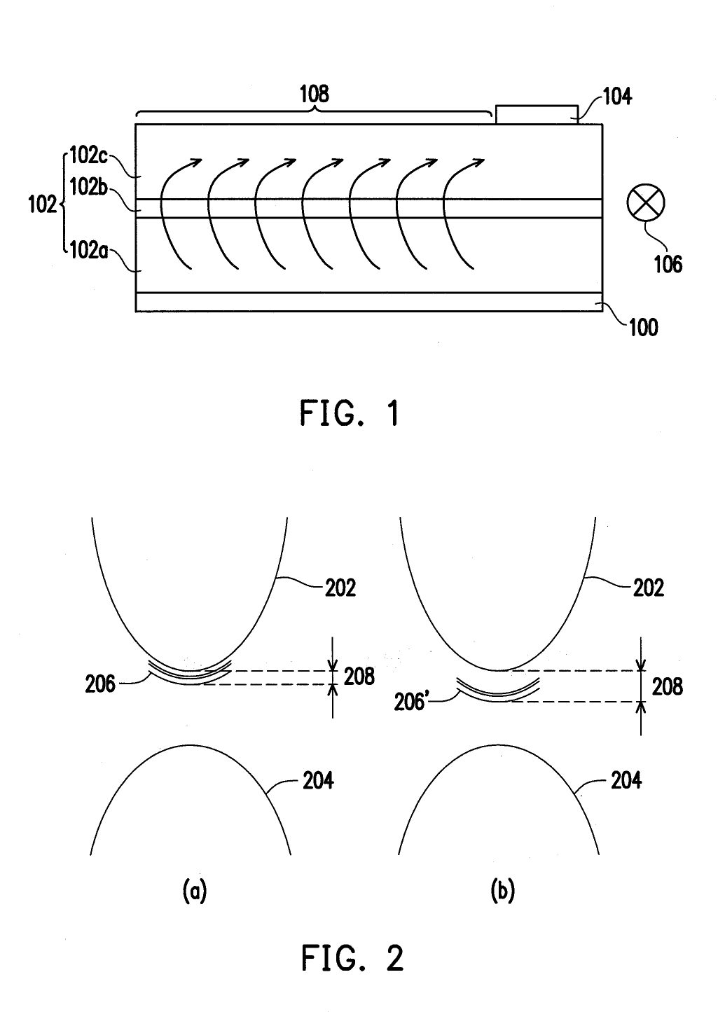

FIG. 1 depicts, in a cross-sectional view, a structure of a light emitting device with the magnetic field according to an embodiment of the disclosure. In FIG. 1, a light emitting diode (LED) is taken as the example. The light emitting diode includes, for example, a bottom electrode 100, a light-emitting structure 102, a top electrode 104. The light-emitting stacked layer 102 includes, for example, a first doped layer 102a, such as P-doped layer, an active layer 102b for emitting light based on recombination of electrons and holes, and a second doped layer 102c, such as N-doped layer. The top electrode 104 can be, for example, not position at the center of the light emitting area 108.

When in operation the current flows from the bottom electrode 100 to the top electrode 104. However, if an external magnetic field in a direction, such as an indication to go in the paper as designated by notion 106, is transversely applied, the Lorenz force is produced to shift and spread the current, as shown in FIG. 1. Alterations or modifications of the conductive types of the electrodes and the direction of the magnetic field are allowed according to the actual design, while the concept remains the same. As a result, the current are transversely shifted and can, still flow from the bottom electrode to the top electrode, which is at the side region of the light emitting area 108. The driving current can more effectively cause the active layer 102b to emit light.

For the structure illustrated in FIG. 1, the two electrodes 100 and 104 are at opposite sides of the light-emitting stacked layer 102, and then the magnetic field is applied parallel to the light emitting area 108, in which the driving current is shifted inside light-emitting stacked layer 102. However, when the electrode is arranged at the same side of the light-emitting stacked layer, a large horizontal-component current is produced, and the direction of magnetic field can be accordingly changed.

Additionally, when considering the quantum effect, the magnetic field applied to the light emitting device, such as at least having a component perpendicular to the active layer, can also improve the conversion efficiency for producing light in the light emitting device. The basic mechanism is that exertion of the perpendicular magnetic field can increase exciting binding energy of the active region, resulting in enhancing the probability of carrier recombination. In more detail, FIG. 2 schematically illustrates a band structure (a) without and (b) with the application of the magnetic field. As shown in FIG. 2, the exciting binding energy 208 represents the energy difference between the lowest level of the binding energy 206 and the bottom edge of the conduction band 202. After applying the magnetic field, the binding energy 206′ between the conduction band 202 and the valence band 204 can be adjusted rather close to the valence band 204 with the aid of the magnetic field, and thereby the exciting binding energy 208 is enhanced due to the lessened lowest level of the binding energy 206′, as indicated by a comparison between (a) and (b) in FIG. 2. In an embodiment, the enhancement of the exciting binding energy is about 0.1 eV with the exertion of the magnetic field. Hence, the internal quantum efficiency (IQE) of the light emitting device can be enhanced effectively owing to the increase in the exciting binding energy.

In general, the improvement in IQE is more significant for the active layer including a nitride-based material, for example. In an embodiment, the nitride-based material can be selected from the group consisting of GaN, AlGaN, InGaN and AlInGaN. In an embodiment, the light-emitting structure emits light with a wavelength ranging between about 265 nm and 580 nm.

For example, the active layer includes multiple quantum well structures separated by barrier structures. In an embodiment, the active layer has at least one quantum well structure, and a thickness of at least one of the quantum well structure is greater than or substantially equal to 1.2 nm at room temperature. In an embodiment, the thickness of at least one of the quantum well structure ranges between 2.6 nm and 16.4 nm at room temperature. In another embodiment, the thickness of at least one of the quantum well structure ranges between 3 nm and 12 nm, possibly between 4 nm and 9 nm, at room temperature. Further, the active layer may have at least one barrier structure arranged alternately with the quantum well structure, and a thickness of at least one of the barrier structure can be greater than or substantially equal to 5 nm at room temperature. The active layer can be made of nitride-based material. Conventionally, the bandgap of the quantum well structures is smaller than that of the barrier structures by choosing their material. For example, the material of the quantum well structures and the barrier structures can be InGaN and GaN, respectively.

It should be noted herein that the intensity of the external magnetic field applied to the light emitting device may have a vertical component greater than or substantially equal to 0.01 gauss (G), for example. Moreover, the magnetic field can be provided by a magnet, a magnetic thin film, an electromagnet, or any other kind of magnetic material, and the number thereof is not limited herein. In addition, the magnetic material may be coupled to the light emitting device itself in the form of a magnetic film or a magnetic bulk, depending upon the thickness thereof. It should also be noted that the direction of the magnetic field may be properly arranged, such as vertical arrangement, horizontal arrangement or any direction relative to the light emitting device, as long as there is a component substantially perpendicular to the active layer. The magnetic material may be a ferromagnetic material, such as Rb, Ru, Nd, Fe, Pg, Co, Ni, Mn, Cr, Cu, Cr2, Pt, Sm, Sb, Pt, or an alloy of the foregoing materials in combination. The magnetic material may also be a ceramic material, such as oxides of Mn, Fe, Co, Cu and V, Cr₂O₃, CrS, MnS, MnSe, MnTe, fluorides of Mn, Fe, Co and Ni, chlorides of V, Cr, Fe, Co, Ni and Cu, bromides of Cu, CrSb, MnAs, MnBi, α-Mn, MnCl₂.4H₂O, MnBr₂.4H₂O, CuCl₂.2H₂O, Co(NH₄)ₓ(SO₄)ₓCl₂.6H₂O, FeCo₃, or FeCo₃.2MgCO₃. The light emitting structure can be an inorganic LED, either in a vertical type, a horizontal type, a thin film type or a flip chip type. That is to say, the light emitting structure can be the horizontal type with two electrodes arranged at the same side of the stacked light-emitting structure or the vertical type with two electrodes at the opposite sides of the stacked light-emitting structure.

In several studies by taking GaN chip as an example with various pumping powers of laser light, the photoluminescence (PL) is generated by the GaN chip and then measured. It turns out that the magnetic field substantially perpendicular to the active layer can significantly improve the PL intensity, and thereby achieve a relative high PL intensity even up to 27% of improvement with the aid of the magnetic field.

Based on the forgoing regards, in a practical application, the light-emitting structure can be combined with magnetic material through various manners such as epoxy, metal bonding, wafer bonding, epitaxial embedding and coating. Embodiments of the light emitting device having the magnetic material adopting foregoing structures are described as follows, respectively. It is noted that the following embodiments in which the first conductivity type is P-type and the second conductivity type is N-type is provided for illustration purposes, and should not be construed as limiting the scope of the disclosure.

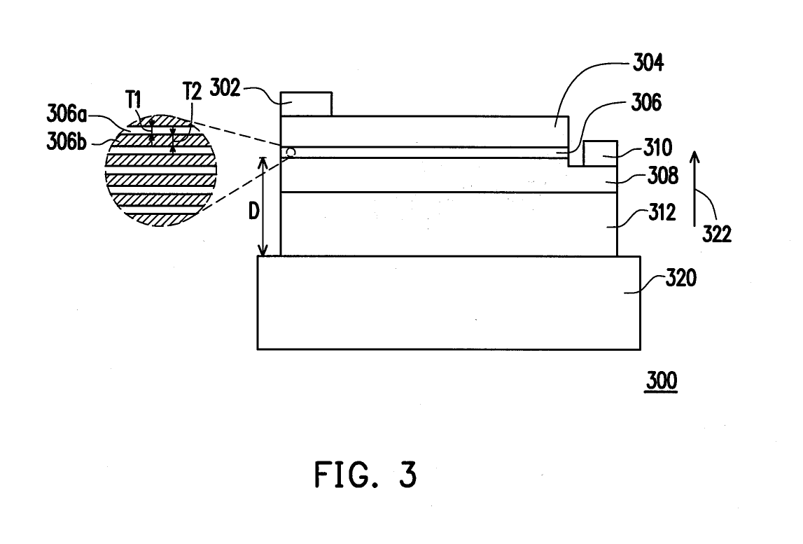

As for a standard LED having a horizontal type structure with two electrodes arranged at the same side of the stacked structure, FIG. 3 is a schematic cross-sectional diagram illustrating a light emitting device according to an embodiment of the disclosure. Referring to FIG. 3, the light emitting device 300 is a horizontal type LED, which includes a light-emitting structure coupled with a magnetic material. In an embodiment, the light-emitting structure is disposed on a magnetic submount 320 through an epoxy, a metal bonding, a wafer bonding, epitaxial embedding, or a coating process. The magnetic submount 320 is, for example, a ferromagnetic layer with a magnetization in a desired direction. In an embodiment, the magnetic-field intensity of the surface of the magnetic submount 320 can be about 0.25 Tesla (T) in vertical component.

The light-emitting structure includes a first electrode 302, a first doped layer 304, an active layer 306, a second doped layer 308, a second electrode 310, and a substrate 312. The substrate 312 is mounted on the magnetic submount 320. The first doped layer 304, such as a P-type doped layer, the active layer 306, and the second doped layer 308, such as an N-type doped layer, jointly form a light-emitting stacked layer disposed on the substrate 312. The first electrode 302 is disposed on the first doped layer 304 and electrically coupled to the first doped layer 304. The second electrode 310 is disposed at the same side of the first electrode 302 and electrically coupled to the second doped layer 308. Accordingly, a horizontal type LED structure is formed. The active layer 306 is disposed between the first doped layer 304 and the second doped layer 308, and capable of generating light when a current flows through it.

The active layer 306 may have at least one quantum well structure 306a and at least one barrier structure 306b, wherein the quantum well structures 306a and the barrier structures 306b are arranged alternately. The thickness T1 of at least one of the quantum well structures 306a is greater than or substantially equal to 1.2 nm at room temperature. In an embodiment, the thickness T1 of at least one of the quantum well structures 306a can range between 2.6 nm and 16.4 nm at room temperature. In another embodiment, the thickness T1 of at least one of the quantum well structures 306a may range between 3 nm and 12 nm at room temperature. In addition, the thickness T2 of at least one of the barrier structures 306b can be greater than or substantially equal to 5 nm at room temperature. The material of the active layer 306 is, for example, nitride-based material, in which the quantum well structure 306a has a small bandgap while the barrier structure 306b has a large bandgap by contrast. People with ordinary skills in the art can make necessary adjustments based on actual demands.

In an embodiment, the shortest distance D between the active layer 306 and the magnetic submount 320 can be not more than 300 μm for ensuring exertion of the magnetic field on the active layer 306. The magnetic field generated by the magnetic submount 320 may have a vertical component 322 substantially perpendicular to the active layer 306. The vertical component 322 of the magnetic field is exerted on the light-emitting structure, such that the IQE of the light emitting device with the thickened quantum well structure 306a can be enhanced effectively to improve the output efficiency of the light emitting device 300.

In other words, the disclosure proposes that the magnetic field having a component perpendicular to the active layer and applied to the light emitting device with a thickened quantum well structure, e.g. a thickness greater than or substantially equal to 1.2 nm, can further increase the exciting binding energy of the active layer. Thereby, more efficiency of carrier recombination is achieved, such that IQE and the output efficiency of the LED are thus remarkably improved. With the external magnetic field applied to the light emitting device, not only the homogeneity of the carrier density in the semiconductor is altered, but also the light emitting efficiency is enhanced. Accordingly, the light emitting device has higher luminance efficiency for optoelectronic transformation even though the amount of injected current remains unchanged.

For illustration purposes, the foregoing disclosure is described in terms of the horizontal type structure, which is illustrated only as an exemplary example, and should not be adopted for limiting the scope of the disclosure to an application of other LED structures. Moreover, the amounts and the manners of stacking the active layer, i.e. quantum well and barrier structures, can be modified based on techniques known to people skilled in the art, and are not limited to the descriptions in the foregoing embodiments.

Following examples are provided to prove that the light emitting device having the thickness of at least one of the quantum well structures greater than or substantially equal to 1.2 nm has better improvement in the IQE and luminous efficiency with the exertion of the magnetic field. These examples are provided merely to illustrate effects upon photoluminescence (PL) and electroluminescence (EL) made by the deployment of the magnetic material in the disclosure, but are not intended to limit the scope of the disclosure.

### Examples

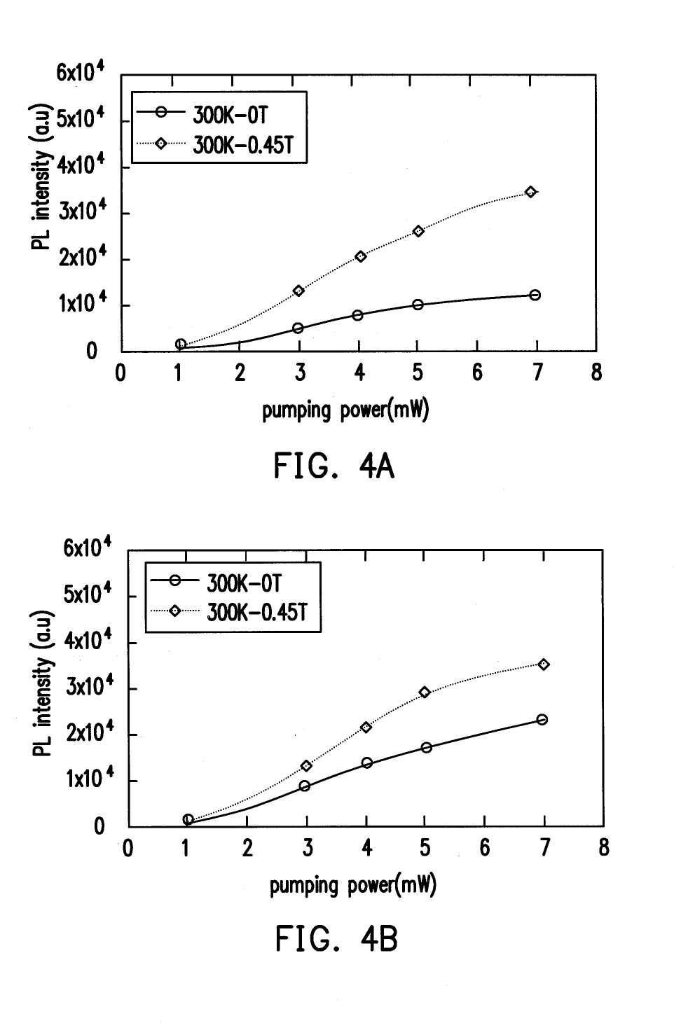

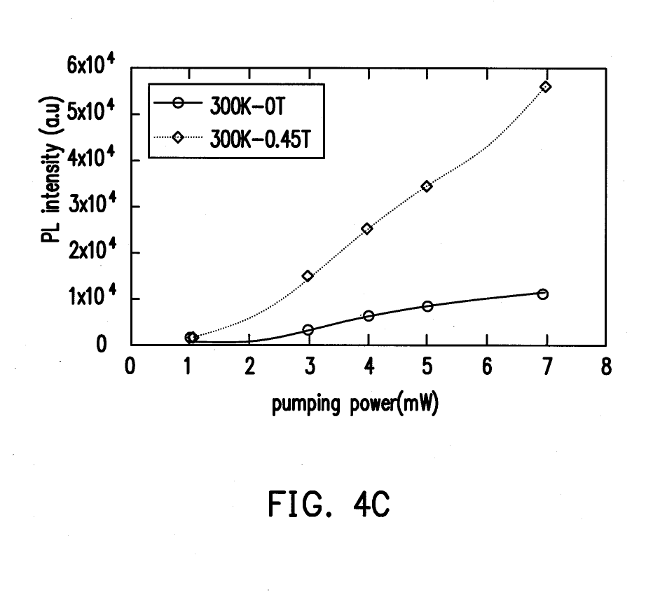

FIGS. 4A-4C schematically illustrate distribution curves of pumping power of laser versus PL intensity of a light emitting device under various conditions of applying the magnetic field according to three experimental examples, respectively. It is noted that experiments in FIGS. 4A-4C are implemented at temperature of approximately 300 kelvin, i.e. 300K.

As shown in FIG. 4A, a nitride-based chip is utilized as a sample, of which the active layer is made of the nitride-based material. The active layer includes at least one quantum well structure separated by barrier structures, wherein the thickness of at least one of the quantum well structure is about 1.2 nm and the thickness of at least one of the barrier structure is about 10 nm at room temperature. Different intensity of the laser is then pumped into the nitride-based chip under the identical conditions except magnitude of the perpendicular magnetic field applied to the chip, so that photoluminescence generated by the material of the chip is then collected and measured. The chips are applied without and with the magnetic field of 0.45 T perpendicular to the active layer and the test results are plotted in FIG. 4A.

Nitride-based chips similar to that described above are utilized as samples for FIGS. 4B-4C, wherein the difference lies in the thickness of at least one of the quantum well structure. In FIG. 4B, the thickness of at least one of the quantum well structure is about 1.64 nm and the thickness of at least one of the barrier structure is about 10 nm at room temperature. In FIG. 4C, the thickness of at least one of the quantum well structure is about 2.04 nm and the thickness of at least one of the barrier structure is about 10 nm at room temperature. Likewise, the chips are applied without and with the magnetic field of 0.45 T perpendicular to the active layer, and the test results of laser-pumped photoluminescence are respectively plotted in FIGS. 4B-4C.

As can be seen from the curves shown in FIGS. 4A-4C, the measured PL intensity in the light emitting device with the applied magnetic field is higher than that in the light emitting device without the applied magnetic field (i.e. 0 T). Accordingly, it turns out that the magnetic field can significantly improve the PL intensity and thereby enhance the luminous efficiency. In particular, when the thickness of at least one of the quantum well structure increases, the enhancement of the PL intensity induced by the applied magnetic field can be even more promoted. In summary, it is clear that the light emitting device having the thickness of at least one of the quantum well structure greater than or substantially equal to 1.2 nm has relative high PL intensity of improvement with the aid of the magnetic field.

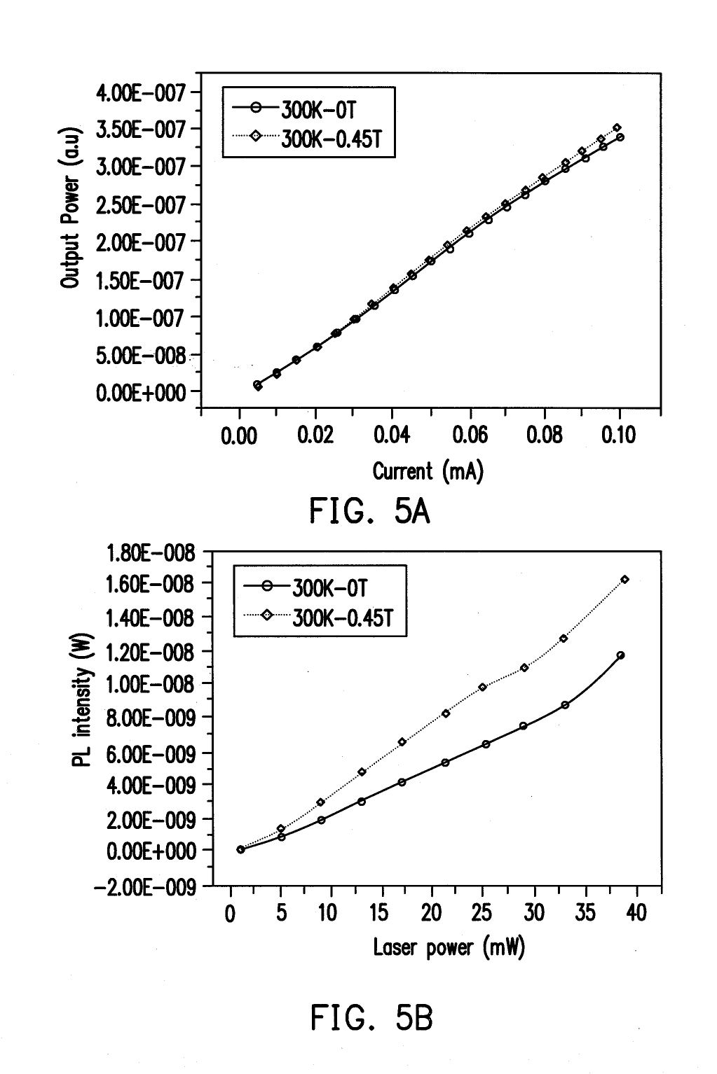

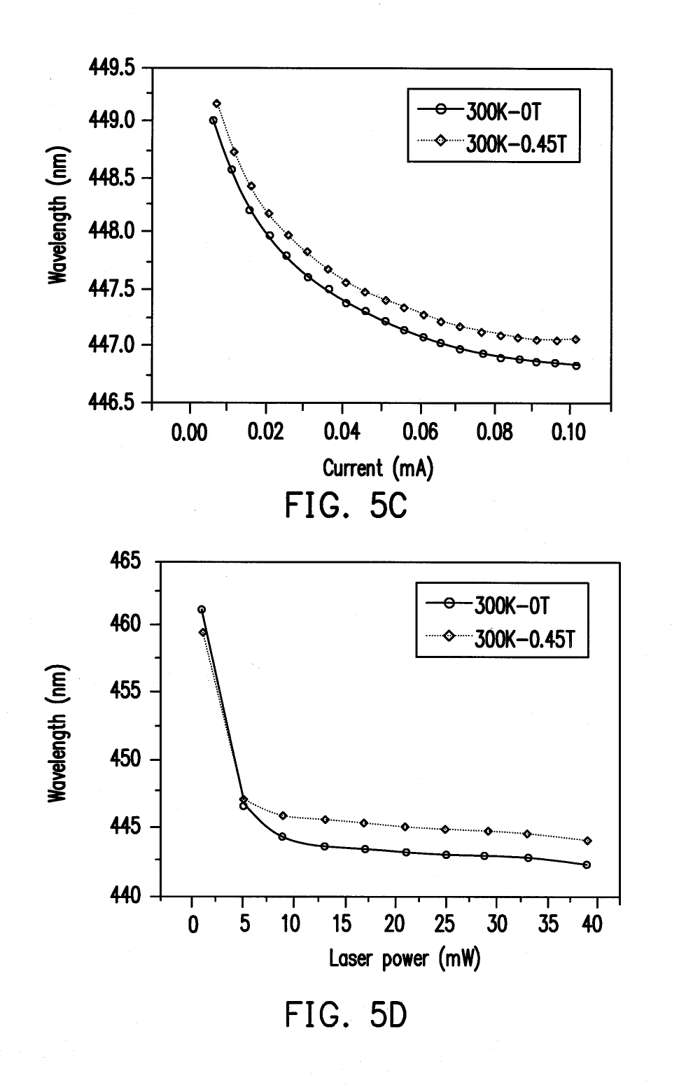

Furthermore, electroluminescence and photoluminescence of another light emitting device having the thickness of at least one of the quantum well structure of 3.3 nm is then examined in consideration of the externally applied magnetic field. FIG. 5A schematically illustrates distribution curves of injection current versus output power of a light emitting device under various conditions of applying the magnetic field according to an experimental example. FIG. 5B schematically illustrates distribution curves of pumping power of laser versus PL intensity of a light emitting device under various conditions of applying the magnetic field according to an experimental example. It is noted that experiments in FIGS. 5A-5B are implemented at temperature of approximately 300 kelvin, i.e. 300K.

As shown in FIG. 5A, effects of the magnetic field upon electroluminescence of a nitride-based chip is measured respectively under the magnetic field of 0 T and 0.45 T perpendicular to the active layer, wherein the thickness of at least one of the quantum well structure is about 3.3 nm and the thickness of at least one of the barrier structure is about 10 nm at room temperature. It can be observed that the measured light output power of the chip is significantly improved by applying the magnetic field. More specifically, the light output power of the chip is enhanced by about 10% in the case of applying the magnetic field of 0.45 T.

As shown in FIG. 5B, photoluminescence of a nitride-based chip is determined in a similar manner described above, wherein the thickness of each single quantum well structure is about 3.3 nm and the thickness of each single barrier structure is about 10 nm at room temperature. Overall, the results indicate that the magnetic field can significantly improve the PL intensity and thereby enhance the luminous efficiency.

In order to verify the above performances is attributed to an increase in exciting binding energy of the active region, influence of magnetic field on the wavelength of emitted light is provided as follows. FIGS. 5C and 5D schematically illustrate distribution curves of injection current and pumping power of laser versus wavelength of light emitted by the light emitting device in accordance with the experimental examples depicted in FIGS. 5A and 5B, respectively. It is noted that experiments in FIGS. 5C-5D are implemented at temperature of approximately 300 kelvin, i.e. 300K.

Since the exciting binding energy represents the energy difference between the lowest level of the binding energy and the edge of the conduction band, the exciting binding energy may get increased as the binding energy lowered as applying the magnetic field thereto. In general, the binding energy is inversely proportional to the wavelength of light emitted by the active layer. That is to say, when the binding energy is decreased, the wavelength of the emitted light is raised. Arnaudov et al. has also demonstrated that a redshift is measured under a moderated magnetic field thereby enhancing the exciting binding energy in “Magnetic-field-induced localization of electrons in InGaN/GaN multiple quantum wells” (Applied Physics Letters, 2003, (83), 13, 2590-2592), of which the entirety is hereby incorporated by reference herein.

As shown in FIGS. 5C and 5D, the measured wavelength of the light emitted from the nitride-based chip with the applied magnetic field is higher than that from the nitride-based chip without the applied magnetic field in regard to both electroluminescence (i.e. FIG. 5C) and photoluminescence (i.e. FIG. 5D). In summary, the light emitting device having a thickened quantum well structure exhibits an improved light emitting efficiency with the aid of the applied magnetic field owing to a decrease in the binding energy. Thus, the device performance can be effectively promoted.

In view of the above, with the enhancement of the exciting binding energy of the semiconductor material in the light emitting device, the improvement in the IQE and the carrier recombination can be achieved. That is, the magnetic field having a component perpendicular to the active layer and applied to the light emitting device with a thickened quantum well structure can increase the IQE, and thereby facilitate for solving the droop effect. Accordingly, the light emitting efficiency of the light emitting device is significantly enhanced.

Even further, the magnetic field can be applied to the light emitting device in the manners as described above, so as to enhance the light emitting efficiency and increase the luminance of the light emitting device.

It will be apparent to those skilled in the art that various modifications and variations can be made to the structure of the disclosure without departing from the scope or spirit of the disclosure. In view of the foregoing, it is intended that the disclosure cover modifications and variations of this disclosure provided they fall within the scope of the following claims and their equivalents.

What is claimed is:

1. A light emitting device, comprising:
a light-emitting structure, having an active layer, wherein the active layer comprises at least one quantum well structure, and a thickness of at least one of the quantum well structure is greater than or substantially equal to 1.2 nm at room temperature; and
a magnetic material, coupled with the light-emitting structure to produce a magnetic field at least having a component perpendicular to a surface of the active layer in the light-emitting structure.

2. The light emitting device according to claim 1, wherein the thickness of at least one of the quantum well structure ranges between 2.6 nm and 16.4 nm at room temperature.

3. The light emitting device according to claim 1, wherein the thickness of at least one of the quantum well structure ranges between 3 nm and 12 nm at room temperature.

4. The light emitting device according to claim 1, wherein the active layer comprises a nitride-based material.

5. The light emitting device according to claim 4, wherein the active layer comprises a material selected from the group consisting of GaN, AlGaN, InGaN and AlInGaN.

6. The light emitting device according to claim 1, wherein the active layer further comprises at least one barrier structure arranged alternately with the quantum well structure.

7. The light emitting device according to claim 6, wherein a thickness of at least one of the barrier structure is greater than or substantially equal to 5 nm at room temperature.

8. The light emitting device according to claim 1, wherein the light-emitting structure emits light with a wavelength ranging between 265 nm and 580 nm.

9. The light emitting device according to claim 1, wherein the light-emitting structure further comprises:
a first doped layer; and
a second doped layer, wherein the active layer is disposed between the first and the second doped layers.

10. The light emitting device according to claim 9, wherein the light-emitting structure further comprises:
a first electrode, coupled to the first doped layer; and
a second electrode, coupled to the second doped layer.

11. The light emitting device according to claim 10, wherein the first electrode and the second electrode are disposed on a same side of the light emitting stack structure.

12. The light emitting device according to claim 10, wherein the first electrode and the second electrode are disposed on opposite sides of the light emitting stack structure.

13. The light emitting device according to claim 1, wherein the magnetic material is a magnetic film or a magnetic bulk.

14. The light emitting device according to claim 1, wherein the magnetic field perpendicular to the surface of the active layer is greater than or substantially equal to 0.01 gauss (G).

15. The light emitting device according to claim 1, wherein a shortest distance between the active layer and the magnetic material is not more than 300 μm.
